(19) United States
(12) Patent Application Publication
(10) Pub. No.: US 2017/0218512 A1
(43) Pub. Date: Aug. 3, 2017

(54) Method of Fabricating High-Conductivity Thick-film Copper Paste Coated with Nano-Silver for Being Sintered in the Air

(71) Applicants: National Cheng Kung University, Tainan (TW); Delta Electronics Inc., Taoyuan City (TW)

(72) Inventors: Wen-Hsi Lee, Tainan (TW); Hsin-Chang Tsai, Taoyuan (TW)

(21) Appl. No.: 15/013,091

(22) Filed: Feb. 2, 2016

(51) Int. Cl. C23C 16/442

(52) U.S. Cl. CPC C23C 16/442

(57) ABSTRACT

A thick-film copper paste is made. A displacement reaction with low cost is used to precipitate nano-silver (Ag) to be grown on copper particles. Thus, the thick-film copper paste is made of the copper powder coated with nano-Ag. The paste can be sintered in the air and is increased in overall electrical conductivity. The copper inside is not oxidized. Its resistance on electromigration is good. Furthermore, the paste can be added with frit as a sintering aid to assist sintering the nano-Ag-coated copper paste. Furthermore, even in a high-temperature heat treatment, the powder of nano-Ag-coated copper is still antioxidant and can replace the silver paste used in the current market.

### TECHNICAL FIELD OF THE INVENTION

The present invention relates to a copper paste; more particularly, relates to fabricating a copper powder coated with nano-silver (Ag) to be sintered in the air at a low temperature to obtain high electrical conductivity, where low cost, low resistance, low-temperature sintering (available for high-temperature sintering according to requirement) and high thermal conductivity are achieved as processing sintering under a non-reducing atmosphere.

### DESCRIPTION OF THE RELATED ARTS

Thick-film conductive paste can be divided into a high-temperature series using glass as a sintering aid and a low-temperature series using polymer resin. The high-temperature sintered conductive paste uses the molten glass for liquid sintering to sinter metal particles together with electrical conductivity enhanced. The low-temperature sintered series soften the polymer resin to contact the metal particles together. Yet, because the metal particles can not be sintered together due to the low temperature, electrical conductivity is not enhanced much.

Silver has a best electrical conductivity, followed by those of copper, gold and aluminum. However, the price of silver is higher than that of copper and the price of gold, whose conductivity is ranked in the third place, is also higher than those of silver and copper. Hence, the first two metal—silver and copper—are taken as the most suitable material for wiring. Copper as a conductor is more popular in decades for its low cost, low resistivity, good adhesion to substrate, excellent weld corrosion resistance, low diffusion resistance, and high resistance to electromigration. But, copper has a strong potential energy of oxidation. Oxidation is prone to happen in fabrication and application. Hence, conductivity decreases and the fabrication needs to be processed with nitrogen having an oxygen partial pressure lower than 10 parts per million (ppm). In addition, conductivity of a copper electrode will be increased following the increase of a temperature for sintering.

For a general thick-film copper paste, regardless of the level of sintering temperature, copper particles can be easily oxidized in the air. Therefore, it must be sintered in a reducing atmosphere to prevent oxidation, where a high temperature for sintering can obtain high electrical conductivity. If a copper paste is sintered at a low temperature, the electrical conductivity might be significantly reduced due to the non-conductive resin contained within.

The two series of silver paste described above have good features; but, silver is a precious metal. In order to reduce material cost, copper as a base metal is chosen. But, if the copper paste has to be sintered in a reducing atmosphere, process cost is bound to be increased. Nevertheless, the low-temperature sintered copper paste needs to use polymer resin for contacting together, which results in bad electrical conductivity.

Hence, the prior arts do not fulfill all users' requests on actual use.

### SUMMARY OF THE INVENTION

The main purpose of the present invention is to fabricate a copper powder coated with nano-Ag to be sintered in the air at a low temperature to obtain high electrical conductivity, where low cost, low resistance, low-temperature sintering (available for high-temperature sintering according to requirement), high thermal conductivity are achieved as processing sintering under a non-reducing atmosphere.

To achieve the above purpose, the present invention is a method of fabricating a thick-film copper paste coated with nano-Ag, comprising steps of: (a) processing a corrosive wash with a copper powder; (b) dissolving the copper powder in ethylene glycol to obtain a copper solution and dissolving a silver powder in ethylene glycol to obtain a silver solution; (c) mixing the copper solution and the silver solution to obtain a mixed solution and processing a displacement reaction with the mixed solution, where silver ions move to surface of the copper powder and are reduced to nano-Ag particles to obtain a layer of the nano-Ag particles on the surface of the copper powder; (d) after filtering and drying the mixed solution, generating a copper powder coated with the nano-Ag particles; and (e) sintering the copper powder coated with the nano-Ag particles under a non-reducing atmosphere to obtain a thick-film copper paste coated with nano-Ag, where the nano-Ag particles is sintered into a molten state to coat the copper powder to prevent copper from being oxidized; and where a layer of the nano-Ag particles coated on the copper powder has a thickness of 100˜400 nanometers (nm), and each of the nano-Ag particles has a size of 40 nm˜70 nm.

### BRIEF DESCRIPTION OF THE DRAWINGS

The present invention will be better understood from the following detailed description of the preferred embodiment according to the present invention, taken in conjunction with the accompanying drawings, in which

FIG. 1 is the structural view showing the thick-film copper powder;

FIG. 2 is the flow view showing the fabrication of the copper paste;

FIG. 3 is the scanning electron microscopy (SEM) view showing the surfaces of the copper particles;

FIG. 4 is the SEM view showing the copper powders sintered under different temperatures; and

FIG. 5 is the view showing the efficiency of the positive electrode of the solar battery using the copper paste.

### DESCRIPTION OF THE PREFERRED EMBODIMENT

The following description of the preferred embodiment is provided to understand the features and the structures of the present invention.

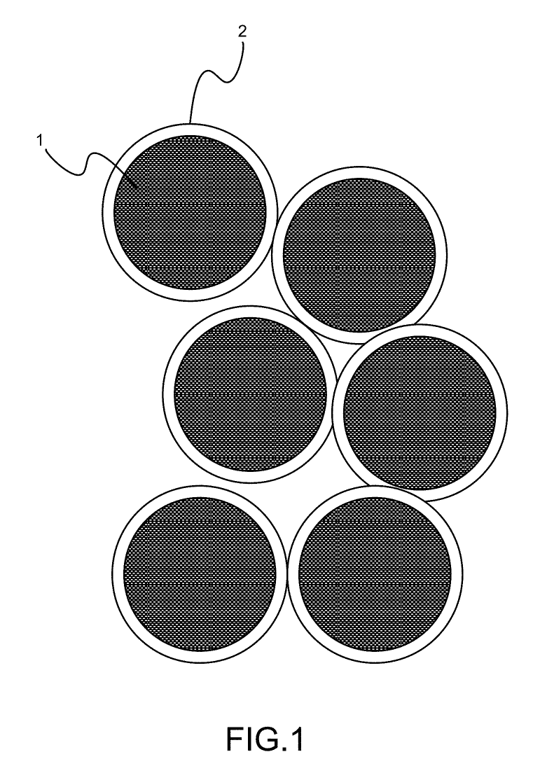

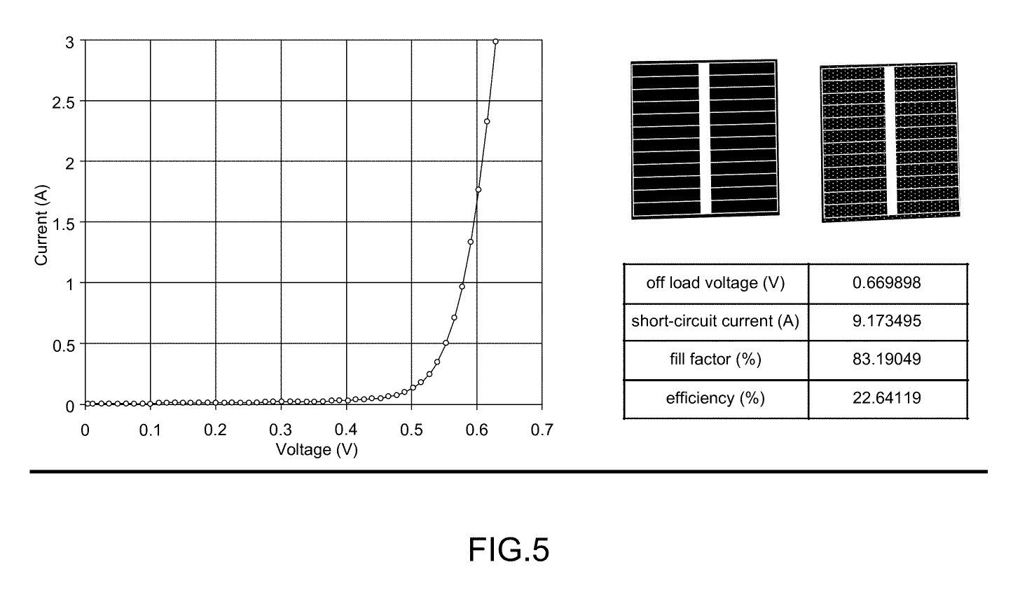

Please refer to FIG. 1˜FIG. 5, which are a structural view showing a thick-film copper powder; a flow view showing fabrication of a copper paste; a SEM view showing surfaces of copper particles; a SEM view showing the copper powders sintered under different temperatures; and a view showing efficiency of a positive electrode of a solar battery using the copper paste. As shown in the figures, the present invention is a method of fabricating a thick-film copper paste coated with nano-silver (Ag). A layer of nano-Ag 2 is grown on surface of particles or powder of copper 1 to coat the copper particles or powder 1 with nano-Ag 2. In a first state-of-use, the present invention uses nano-Ag for solving problems of low conductivity and easy oxidization of low-temperature copper paste, where the advantages of nano-Ag include high electrical conductivity, strong oxidation resistance and low melting point. Nano-Ag having a low melting point is used as an adhesive between copper particles or powder by being liquefied after heat treatment. Furthermore, since nano-Ag 2 is coated on the surface of the copper particles or powder 1, copper internally contained is not oxidized during the heat treatment, whose structure is shown in FIG. 1.

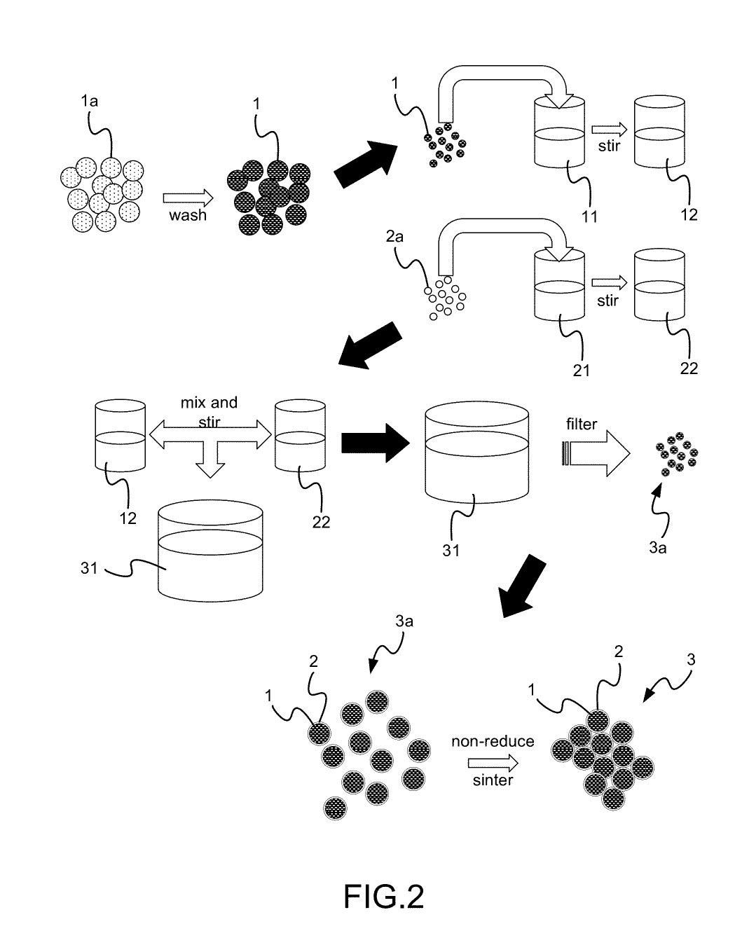

The flow of the present invention is shown in FIG. 2, comprising the following steps:

(a) A copper powder 1a is processed through a corrosive wash, where the copper powder 1a is a flake copper powder.

(b) The washed copper powder 1 is dissolved in ethylene glycol 11 to form a copper solution 12 and a silver powder 2a is dissolved in ethylene glycol to form a silver solution 22.

(c) The copper solution 12 is mixed with the silver solution 22 to form a mixed solution 31 with a molarity of 0.05˜0.2 molars. The mixed solution 31 is processed through a displacement reaction. Therein, replacement is happened between copper and silver in the mixed solution 31 with the copper powder dissociated into the mixed solution 31 and silver ions precipitated out on surface of the copper powder. The replacement is processed at 20˜30 celsius degrees (° C.) for 30˜90 minutes (min), so that freed silver ions are moves toward the washed surface of the copper powder 1 to be reduced to nano-Ag for forming a layer of nano-Ag 2 on the washed surface of the copper powder 1.

(d) After filtering and drying the mixed solution 31, a copper powder coated with nano-Ag 3a is obtained.

(e) The copper powder coated with nano-Ag 3a is sintered under a non-reducing atmosphere, where nano-Ag 2 is sintered into a molten state to coat the copper powder 1 to prevent copper from being oxidized. Thus, a thick-film copper paste coated with nano-Ag 3 is obtained. Therein, the copper powder coated with nano-Ag 3a has a content of 80˜95 weight percents in the thick-film copper paste 3; the layer of nano-Ag 2 has a thickness of 100 nm˜400 nm; and nano-Ag has a particle size of 40 nm˜70 nm.

Thus, a novel method of fabricating a thick-film copper paste coated with nano-Ag is obtained.

The present invention uses a galvanic displacement reaction to fabricate a copper powder coated with nano-Ag and obtain its low sintering temperature and low conductivity. As shown in FIG. 2, nano-Ag 2 is generated on surface of the copper powder 1 to be used as an adhesive for reducing contact resistance of copper powder. At a low temperature of 300° C. under a reducing atmosphere, nano-Ag 2 is sintered into a molten state to coat the copper powder 1 for preventing copper from being oxidized and pores from being filled by molten copper. Thus, a copper paste coated with nano-Ag is fabricated with conductivity improved, density increased while a sintering temperature is reduced.

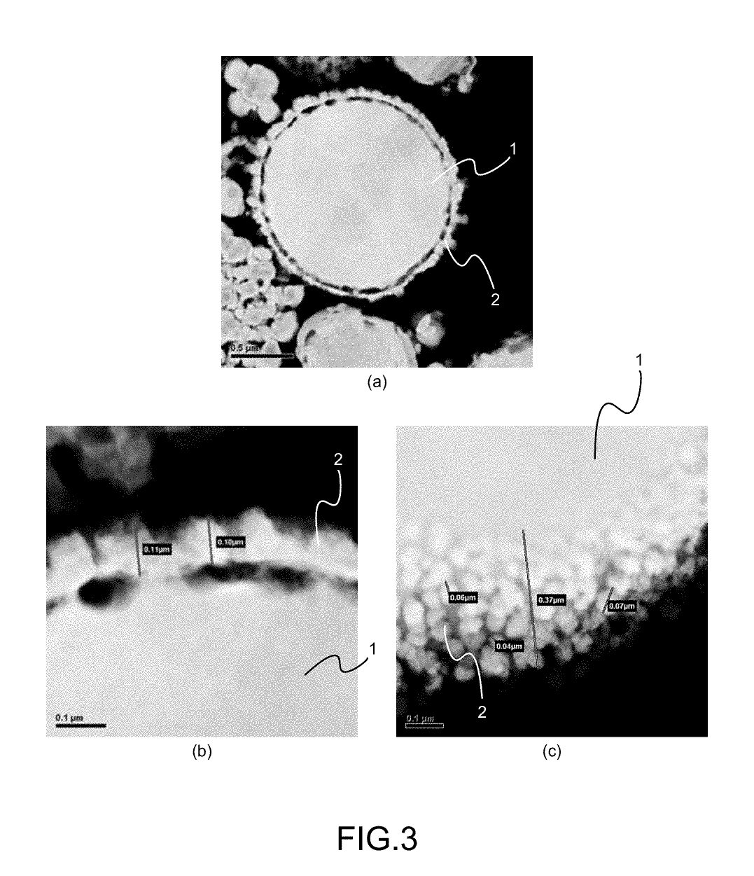

In FIG. 3, part (a) shows a SEM view of surface of a copper powder 1 completely coated with nano-Ag 2. Part (b) shows that nano-Ag 2 has a coating thickness about 100 nm˜110 nm and nano-Ag 2 is evenly coated on the surface of the copper powder 1. Part (c) magnifies the view for clearly showing particle sizes of nano-Ag 2 coated on the surface of the copper powder 1, where a particle size of nano-Ag 2 is about 40 nm˜70 nm and a coating thickness even reaches 370 nm.

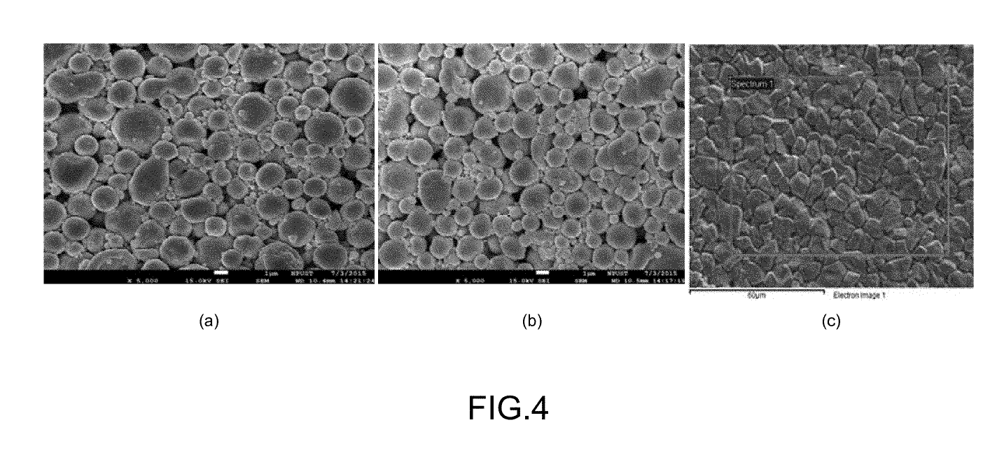

In FIG. 4, part (a) has a sintering environment set at 200° C. with a heating rate of 3° C. per minute (° C./min). After holding the sintering temperature for 30 minutes, a sheet resistance is measured and converted to electrical conductivity. Part (b) has the temperature raised to 250° C. with the same heating rate and holding-temperature time period. By observing part (a) and part (b), it is found that the surface of the copper powder coated with nano-Ag becomes smoother than the previous rough surface. Besides, some small pieces of nano-Ag have been fused together; yet there are still very much pores and the whole structure is not very dense. Since the sintering temperature is raised to 250° C. to observe the microstructure and find the sintering temperature is not ideal, the temperature is then raised to 300° C. for part (c). As is observed, all nano-Ag on the surface of the copper powder is fully sintered into a molten state and all pores are filled by the molten nano-Ag. Hence, the overall density is relatively improved a lot with very small porosity, which can be observed from cross section.

With regard to electricity comparison, the present invention uses three different sintering temperatures for the copper paste coated with nano-Ag, including 200° C., 250° C. and 300° C. With a heating rate of 3° C./min and a holding-temperature time period of 15 min, the copper paste is compared with commercially available silver pastes sintered at low temperatures, where the result is shown in Table 1.

TABLE 1

| | 200° C. | 250° C. | 300° C. |
|---|---|---|---|
| 3° C./min | 0.0700 Ω/sq | 0.0673 Ω/sq | 0.0057 Ω/sq |
| holding 15 min | | | |
| 3° C./min | 0.0381 Ω/sq | 0.0422 Ω/sq | 0.0061 Ω/sq |
| holding 15 min | | | |

The resistance shown in Table 1 is fully compliant with the microstructure shown in FIG. 4. It proves that, after being sintered under 300° C., molten nano-Ag coated on copper particles or powder is used as an adhesive between the copper particles or powder so that the microstructure is still very dense even being sintered under a low temperature. The dense microstructure shows a lowest sheet resistance for the copper coated with nano-Ag at 300° C. with 15 minutes of holding temperature. By converting the sheet resistance into resistivity, a resistivity value considered as close to that of a currently commercialized nano-Ag paste is obtained. This means that the present invention successfully fabricated a thick-film copper paste coated with nano-Ag for being sintered in the air and obtaining a high electrical conductivity. The novel copper paste fabricated according to the present invention overcomes the problem of low conductivity of low-temperature copper paste after being processed through a low-temperature heat treatment. The present invention uses low-temperature heat treatment and has nano-Ag coated on copper for processing sintering in the air and preventing oxidization of copper.

Table 2 shows conductivity of the copper paste sintered under different parameters. As shown in the table, when the particle size of nano-Ag is too big, low-temperature sintering may not be available. On the other hand, when the thickness of the coated nano-Ag is not enough, oxidation of internal copper particles can not be avoided and conductivity is affected thereby. Nevertheless, if the solid content of nano-Ag coated on copper in the paste is too small, porosity will be too high to further affect conductivity. Besides, too low or too high sintering temperatures also influence conductivity of the copper paste.

TABLE 2

| | nano-Ag | | | | |
|---|---|---|---|---|---|
| | particle | nano-Ag | | sintering | |
| | size | thickness | nano-Ag | temperature | resistivity |
| | (nm) | (nm) | content | (° C.) | (Ω) |
| 1 | 20 | 200 | 90% | 300 | <1 × 10⁻⁵ |
| 2 | 40 | 200 | 90% | 300 | <1 × 10⁻⁵ |
| 3 | 60 | 200 | 90% | 300 | <1 × 10⁻⁵ |
| 4 | 80 | 200 | 90% | 300 | <1 × 10⁻⁵ |
| 5 | 100 | 200 | 90% | 300 | 5 × 10⁻³ |
| 6 | 40 | 100 | 90% | 300 | 1 × 10⁻⁴ |
| 7 | 40 | 200 | 90% | 300 | >1 × 10⁻⁵ |
| 8 | 40 | 300 | 90% | 300 | >1 × 10⁻⁵ |
| 9 | 40 | 400 | 90% | 300 | >1 × 10⁻⁵ |
| 10 | 40 | 500 | 90% | 300 | >1 × 10⁻⁵ |
| 11 | 40 | 200 | 70% | 300 | 1 × 10⁻³ |
| 12 | 40 | 200 | 75% | 300 | 1 × 10⁻⁴ |
| 13 | 40 | 200 | 80% | 300 | >1 × 10⁻⁵ |
| 14 | 40 | 200 | 85% | 300 | >1 × 10⁻⁵ |
| 15 | 40 | 200 | 90% | 300 | >1 × 10⁻⁵ |
| 16 | 40 | 200 | 95% | 300 | >1 × 10⁻⁵ |
| 17 | 40 | 200 | 90% | 250 | 1 × 10⁻⁴ |
| 18 | 40 | 200 | 90% | 300 | <1 × 10⁻⁵ |
| 19 | 40 | 200 | 90% | 400 | <1 × 10⁻⁵ |
| 20 | 40 | 200 | 90% | 500 | <1 × 10⁻⁵ |
| 21 | 40 | 200 | 90% | 600 | <1 × 10⁻⁵ |
| 22 | 40 | 200 | 90% | 700 | <1 × 10⁻⁵ |
| 23 | 40 | 200 | 90% | 800 | 1 × 10⁻⁴ |
| 24 | 10 | 200 | 90% | 300 | <1 × 10⁻⁵ |
| 25 | 10 | 50 | 90% | 300 | 1 × 10⁻³ |

As shown in FIG. 5, the present invention sinters the copper paste at a low temperature in the air to be applied to a positive electrode of silicon-based solar battery. The efficiency of the silicon-based solar battery reaches up to more than 21%, which is relatively close to that of a general silicon-based solar battery using a positive electrode of silver. Hence, the thick-film copper paste fabricated according to the present invention is successfully applied to silicon-based solar battery.

Table 3 shows characteristics of silver-conducted thick-film paste sintered at different temperatures. Since silver is a precious metal, the present invention chooses a base metal copper as a material for saving cost. But, if the copper paste needs to be sintered in a reducing atmosphere, the cost of the manufacturing process is bound to increase. Therefore, the present invention provides a thick film copper paste coated with nano-Ag to be sintered at a low temperature and to obtain high electrical conductivity.

TABLE 3

| | High-temperature | Low-temperature | Low-temperature |
|---|---|---|---|
| | high-conductivity | low-conductivity | high-conductivity |
| | Ag-coated paste | Ag-coated paste | Ag-coated paste |
| Sintering | 800~900° C. | 150~250° C. | 250~300° C. |
| temperature | | | |
| Conductivity | 10⁻⁶ Ω · cm | 10⁻⁵ Ω · cm | 10⁻⁶ Ω · cm |
| Process cost | High | Low | Low |
| Material cost | High | High | Low |
| Main | Silicon-based | Membrane switch | Silicon-based |
| applications | solar battery | Touch panel | solar battery |
| | Passive | RFID | Passive |
| | component | | Component |
| | LED heat | | LED heat |
| | dissipation board | | dissipation board |
| | | | High-power PCB |

The present invention is a great break-through to electrode material in the current industries. Electroplating copper electrode of printed circuit board (PCB) can be replaced to overcome the need of expensive process in yellow developing and to solve the problem of plating bath pollution. The expensive silver electrode material is also replaced in screen printing for solar battery board, LED board and passive component substrate. In addition, the problem that copper electrode for screen printing needs to be processed in a reducing atmosphere with an expensive cost is also solved.

Furthermore, even though the copper powder coated with nano-Ag fabricated according to the present invention is processed at a high temperature (>450° C.) the feature of anti-oxidation remains. As different from the first state-of-use of using nano-Ag as a sintering aid, a second state-of-use adds glass as a sintering aid to help sintering the copper coated with nano-Ag at a high temperature for replacing the applications of silver paste in the current market.

Accordingly, based on process conditions and application characteristics, the copper coated with nano-Ag is divided into two categories for the present invention: the first category is the low-temperature conductive ink of copper coated with nano-Ag as described in the first state-of-use; and the second category is the high-temperature conductive ink of copper coated with nano-Ag as described in the second state-of-use.

The low-temperature conductive ink of copper coated with nano-Ag has an ink characteristic that conductive path is formed by contacting copper particles. The mechanism is that, after turning silver particles into nano-scale, a low-temperature molten state of nano-Ag obtains a directly-lowered melting point. By adding the nano-Ag particles with the lowered melting point, copper particles are fused to contact in between for forming a continuous film of conductive copper, where the film comprises a curing agent (a polymer resin, an inorganic glass, etc.), the copper powder coated with nano-Ag and other additives. Generally, the process temperature is about 250° C.˜450° C. owing to nano-Ag. Because the conductive path is mainly formed by contacting copper particles, a content of copper coated with nano-Ag in the ink and a stacking density of the copper particles have direct impact on resistivity, which is about 10⁻⁵ watts·centimeter (W·cm) or more. This kind of ink of copper powder is usually formed into a flake copper powder for increasing contact area and stacking density. Dispersants and rheology modifier are also common additives. Common applications include a printed wiring on a membrane switch of keyboard; a printed conductive wiring on a resistive or capacitive touch panel; an electrode wiring in a display; and a chip soldering ink used in a PCB.

The conductive ink of copper coated with nano-Ag mainly comprises the copper powder coated with nano-Ag; an organic binder and its additives (dispersants or rheology modifier); and frit. The conductive ink of copper coated with nano-Ag mainly uses glass and silver powder sintered under the high temperature for achieving conductivity, where the glass is softened under a high temperature to obtain good adhesion to substrate and reaction interface. In general, the resistivity of the ink is up to about 10⁻⁵ W·cm or less, which is close to the resistivity of silver. However, for reaching the softening point of glass and the sintering temperature of silver, the process is mostly operated at a high temperature about 600° C. or higher. The ink is usually applied to inner electrode of passive component; terminal electrode of surface mount device (SMD); electrode of light-emitting-diode (LED) ceramic radiating substrate; and upper silver electrode of silicon-based solar battery—a currently popular application.

Hence, the present invention uses a low-cost replacement reaction to precipitate nano-Ag particles to be grown on copper for forming a thick-film conductive paste of copper powder coated with nano-Ag, where the paste is increased in overall conductivity; copper inside is not oxidized; a lower cost than that of the original silver coated is obtained; electromigration resistance is good; and, after copper is coated with nano-Ag, sintering can be processed at a low temperature in the air without being oxidized.

To sum up, the present invention is a method of fabricating a thick-film copper paste coated with nano-Ag, where a low-cost replacement reaction is used to coat nano-Ag particles on surface of copper powder for achieving low cost, low resistance and high thermal conductivity; sintering is processed at a low temperature (a high-temperature sintering is also available according to requirement); and a conductive paste made of the copper powder coated with nano-Ag can be sintered under a non-reducing atmosphere.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

1. A method of fabricating a thick-film of copper paste coated with nano-silver (Ag), comprising steps of:
(a) processing copper powder with a corrosive wash;
(b) dissolving said washed copper powder in ethylene glycol to obtain a copper solution and dissolving silver powder in ethylene glycol to obtain a silver solution;
(c) mixing said copper solution and said silver solution to obtain a mixed solution and processing a displacement reaction with said mixed solution, wherein silver ions move to surface of said copper powder and are reduced to nano-Ag particles to obtain a layer of said nano-Ag particles on said surface of said copper powder;
(d) after filtering and drying said mixed solution, obtaining a copper powder coated with said nano-Ag particles; and
(e) sintering said copper powder coated with said nano-Ag particles under a non-reducing atmosphere to obtain a thick-film of copper coated with nano-Ag, wherein the nano-Ag particles are sintered into a molten state to coat said copper powder to prevent copper from being oxidized; and wherein the thick-film of said nano-Ag particles coated on said copper powder has a thickness of 100˜400 nanometers (nm), and each of said nano-Ag particles has a size of 40 nm˜70 nm.

2. The method according to claim 1, wherein said copper powder is a flake copper powder.

3. The method according to claim 1, wherein, in step (c), said displacement reaction is processed at a temperature of 20˜30 Celsius degrees (° C.) for a time of 30˜90 minutes (min).

4. The method according to claim 1, wherein, in step (c), said mixed solution has a molarity of 0.05˜0.2 molars.

5. The method according to claim 1, wherein said copper powder coated with said nano-Ag particles has a content of 80˜95 weight percent in said thick-film.

6. The method according to claim 1, wherein, in step (e), said sintering is processed at a temperature lower than 300° C.

7. The method according to claim 1, wherein, in step (e), said sintering has a heating rate of 3° C. per minute before a time of holding temperature for 15˜30 min.

8. The method according to claim 1, wherein said thick-film further comprises a curing agent of a polymer resin with an inorganic glass and an additive is selected from a group consisting of a dispersant and a rheology modifier.

9. The method according to claim 1, wherein said thick-film has a resistance greater than 10⁻⁵ watts·centimeter (W·cm).

10. The method according to claim 8, wherein said thick-film is applied to an object selected from a group consist of a printed wiring on a membrane switch of keyboard; a printed conductive wiring on a device selected from a group consist of a resistive touch panel and a capacitive touch panel; an electrode wiring in a display; and a chip soldering ink used in a printed circuit board.

11. The method according to claim 1, wherein, in step (e), said sintering is processed at a high temperature and said high temperature is higher than 600° C.

12. The method according to claim 1, wherein said thick-film comprises said copper powder coated with said nano-Ag particles; an organic binder; an additive; and frit; and wherein said additive is selected from a group consist of a dispersant and a rheology modifier.

13. The method according to claim 12, wherein said thick-film is applied to an object selected from a group consist of an inner electrode of a passive component; a terminal electrode of a surface mount device (SMD); an electrode of a light-emitting-diode (LED) ceramic radiating substrate; and an upper silver electrode of a silicon-based solar battery.
